(19) United States
(12) Patent Application Publication
(10) Pub. No.: US 2024/0379628 A1
(43) Pub. Date: Nov. 14, 2024

(54) SPLICING UNIT FOR DISPLAY PANEL

(71) Applicant: HUA YANG Precision Machinery Co.,Ltd, Tainan City (TW)

(72) Inventor: Yu-Jen CHEN, Taichung City (TW)

(21) Appl. No.: 18/336,542

(22) Filed: Jun. 16, 2023

(30) Foreign Application Priority Data
May 10, 2023 (TW) 112117327

(51) Int. Cl. H01L 25/075; H01L 33/62

(52) U.S. Cl. CPC H01L 25/0753; H01L 33/62

(57) ABSTRACT

A splicing unit for display panels includes: a splicing board having an upper surface on which a plurality of main wires are disposed and at least one lateral surface defined as a splicing surface; a lead board having a lower surface on which a plurality of lead wires are disposed, at least one lateral surface defined as a lead splicing surface being flush with the splicing surface substantially, and an upper surface attached to a lower surface of the splicing board; and a plurality of bridging wires each having one end connected to one of the main wires and positioned proximate to the upper surface of the splicing board, a body extending and crossing the splicing surface and the lead splicing surface, and the other end connected to one of the lead wires and positioned proximate to the lower surface of the lead board.

### BACKGROUND OF THE INVENTION

### 1. Technical Field

The present disclosure relates to display panel splicing technology, and more particularly to a splicing unit for display panels.

### 2. Description of Related Art

Known demand for splicing display panels is currently concentrated on Micro LED display panels and OLED display panels. Display panel splicing is aimed at splicing multiple small display panels to form a large-sized panel to achieve an advantage, i.e., quick splicing-based production of large-sized panels is feasible because of the ease of manufacturing small display panels.

CN 215010856 U, which is about glass circuit board splicing technology, discloses a spliced glass circuit board comprising two glass circuit boards on which multiple connecting pieces are disposed. The connecting pieces comprise a first clamping part and a second clamping part which are made of metal and clamped onto circuits on a first glass plate and a second glass plate to constitute an electrical connection and thus form a simple and firm connecting structure.

The aforesaid prior art is characterized by connections between glass circuit boards such that circuits at adjacent glass circuit boards are connected. The technique is applicable to the scenario where multiple glass circuit boards are united and thus controlled by a master controller instead of the scenario where multiple glass circuit boards each come with a standalone controller. Furthermore, the metallic clamping parts are each disposed between the adjacent glass circuit boards, disadvantageously increasing the distance between the adjacent glass circuit boards. When applied to Micro LED display panels or OLED display panels, the aforesaid technique disadvantageously increases the pixel distance between two adjacent glass circuit boards, leading to image distortions or anomalies.

Referring to FIG. 7, to allow each glass circuit board 81 to come with a standalone controller (not shown), it will be necessary for circuits on the glass circuit boards 81 to undergo lead concentration and thus for a lead zone Z to be defined on one side of each glass circuit board 81 to accommodate a lead Z1 for connecting to a control chip (not shown). However, the lead zone Z still requires the reservation of a specific width. Likewise, the width causes an increase in the pixel distance between two adjacent glass circuit boards 81, leading to image distortions or anomalies.

Therefore, removal of the lead zone Z and retention of the glass circuit boards 81 to accommodate standalone controllers and thereby form a splicing framework can ensure a normal distance between the pixels upon completion of the splicing process and preclude image distortions or anomalies.

Furthermore, removal of the lead zone Z and direct formation of leads on rear sides of the glass circuit boards 81 can result in an abrupt rise in cost as well as the high likelihood of causing an approaching clamping tool to press and damage the circuits. As a result, the direct formation of leads on rear sides of the glass circuit boards 81 is not a good solution at the present moment.

### BRIEF SUMMARY OF THE INVENTION

It is an objective of the disclosure to provide a splicing unit for display panels to remove a conventional lead zone but enable a controller to be mounted in place so as to splice two adjacent splicing boards without increasing the distance therebetween.

To achieve the above and other objectives, the disclosure provides a splicing unit for display panels, comprising: a splicing board having an upper surface and a lower surface, with a plurality of main wires disposed on the upper surface of the splicing board, the splicing board having at least one lateral surface defined as a splicing surface; a lead board having an upper surface and a lower surface, with a plurality of lead wires disposed on the lower surface of the lead board, the lead board having at least one lateral surface defined as a lead splicing surface, wherein the upper surface of the lead board is attached to the lower surface of the splicing board, and the splicing surface of the splicing board is substantially flush with the lead splicing surface of the lead board; and plurality of bridging wires connected to the plurality of main wires and the plurality of lead wires, wherein each of the bridging wires has an end connected to one of the main wires and positioned proximate to the upper surface of the splicing board, and a body of the bridging wire extends and crosses the splicing surface of the splicing board and the lead splicing surface of the lead board, allowing another end of the bridging wire to be connected to one of the lead wires and positioned proximate to the lower surface of the lead board.

Therefore, the disclosure discloses dispensing with a conventional lead zone but allowing a controller to be mounted in place to splice a splicing board with another splicing board without causing an increase in the distance between the two adjacent splicing boards.

### BRIEF DESCRIPTION OF THE SEVERAL VIEWS OF THE DRAWINGS

FIG. 1 is a perspective view of a splicing unit for display panels according to a first preferred embodiment of the disclosure.

FIG. 2 is a perspective view of the splicing unit for display panels viewed from bottom according to the first preferred embodiment of the disclosure.

FIG. 3 is a side view of the splicing unit for display panels according to the first preferred embodiment of the disclosure.

FIG. 4 is an enlarged view of FIG. 3.

FIG. 5 is a side view of another splicing unit for display panels according to a second preferred embodiment of the disclosure.

FIG. 6 is a side view of yet another splicing unit for display panels according to a third preferred embodiment of the disclosure.

FIG. 7 (prior art) is a perspective view of conventional glass circuit boards.

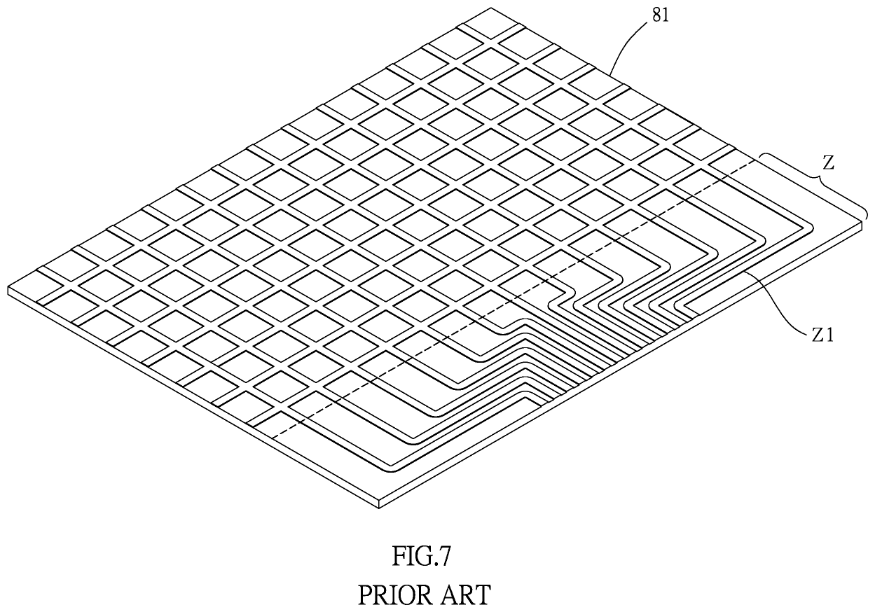

### DETAILED DESCRIPTION OF THE INVENTION

The technical features of the disclosure are hereunder illustrated with preferred embodiments, depicted with accompanying drawings, and described below.

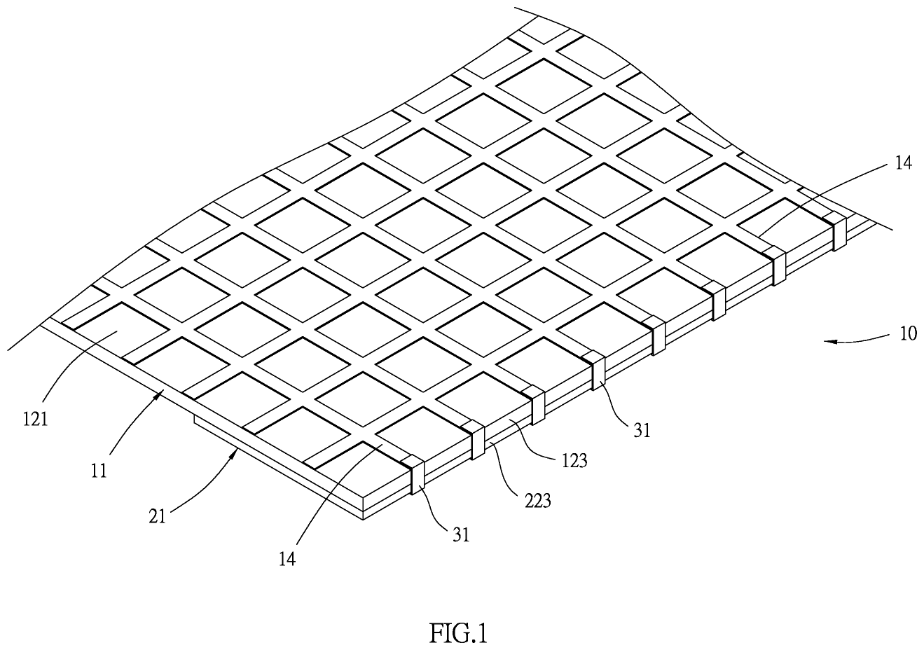

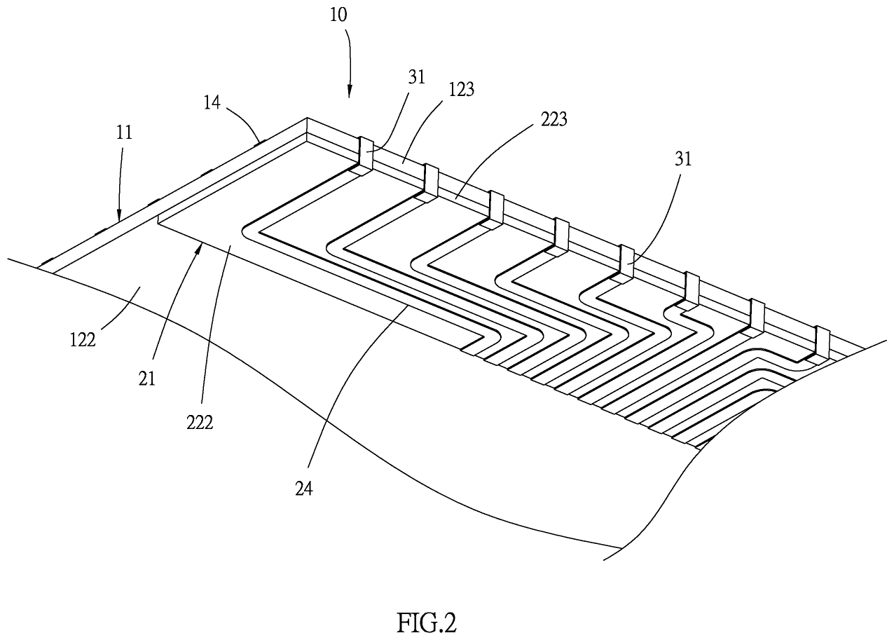

Referring to FIG. 1 through FIG. 4, a splicing unit 10 for display panels according to a first preferred embodiment of the disclosure essentially comprises a splicing board 11, a lead board 21 and a plurality of bridging wires 31.

The splicing board 11 has an upper surface 121 and a lower surface 122. A plurality of main wires 14 are disposed on the upper surface 121 of the splicing board 11. The splicing board 11 has a lateral surface defined as a splicing surface 123. In the first embodiment, the splicing board 11 is a glass circuit board or any other known board on which a circuit is disposed. Furthermore, to facilitate illustration by the accompanying drawings, the plurality of main wires 14 shown in the accompanying drawings are neither drawn to scale nor drawn to reflect the correct number of the main wires 14. In practice, a splicing board with known specifications comes in different dimensions. Take a 9.8-inch splicing board as an example, it has 193 wires in the X-direction and 216*3 wires in the Y-direction (with 216 being multiplied by a factor of 3 because of RGB LED wires). Since the wires are densely distributed on the splicing board and thus difficult to discern and identify, the wires are schematically depicted with diagrams.

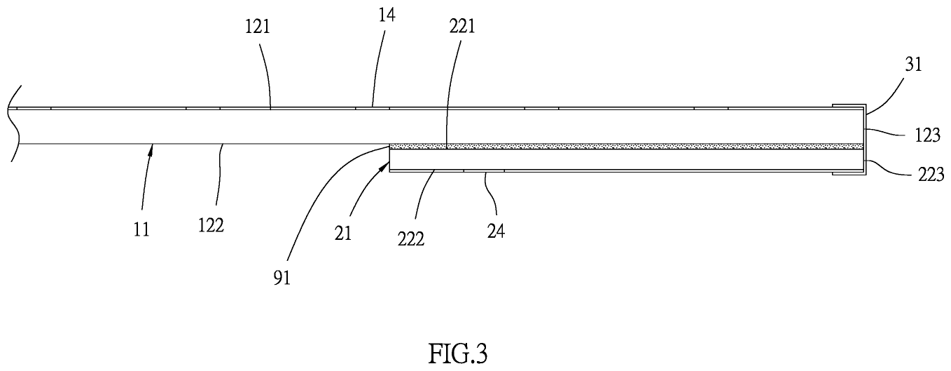

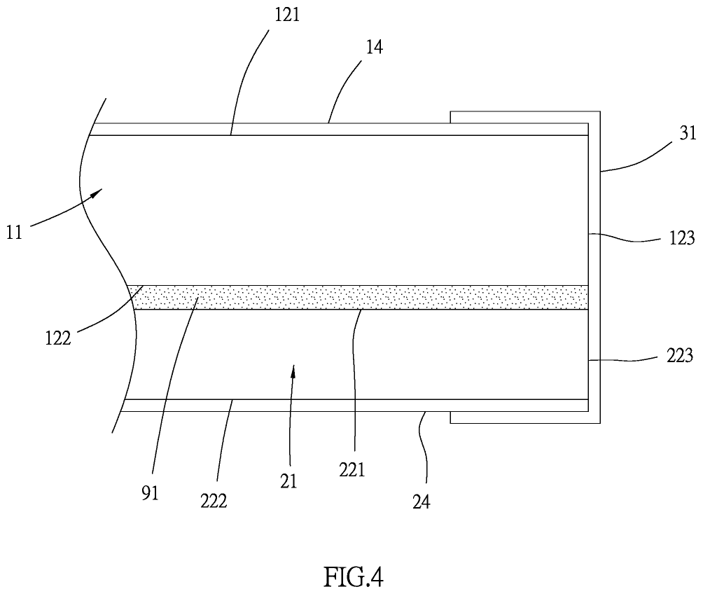

The lead board 21 has an upper surface 221 and a lower surface 222. A plurality of lead wires 24 are disposed on the lower surface 222 of the lead board 21. The lead board 21 has a lateral surface defined as a lead splicing surface 223. The upper surface 221 of the lead board 21 is attached to the lower surface 122 of the splicing board 11. The splicing surface 123 of the splicing board 11 is substantially flush with the splicing surface 123 of the lead board 21. In the first embodiment, the lead board 21 is adhered to the splicing board 11 with an adhesive 91. In practice, the splicing board 11 has two adjacent lateral surfaces defined as two splicing surfaces 123, whereas two lead boards 21 each have the lead splicing surface 223. However, in the first embodiment, for the sake of explanation, the splicing board 11 and the lead board 21 have their respective lateral surfaces defined as the splicing surface 123 and the lead splicing surface 223, respectively. Furthermore, in practice, the adhesive 91 is of a thickness too small to be shown in the accompanying drawings. However, for the sake of illustration, as shown in FIG. 3 and FIG. 4, the adhesive 91 is depicted to be of a greater thickness than it actually is. Moreover, the lead board 21 is a glass circuit board or any other known board on which a circuit is disposed.

The plurality of bridging wires 31 are connected to the plurality of main wires 14 and the plurality of lead wires 24.

Each bridging wire 31 has one end connected to one of the main wires 14 and positioned proximate to the upper surface 121 of the splicing board 11. The body of the bridging wire 31 extends and crosses the splicing surface 123 of the splicing board 11 and the lead splicing surface 223 of the lead board 21. The other end of each bridging wire 31 is connected to one of the lead wires 24 and positioned proximate to the lower surface 222 of the lead board 21. In the first embodiment, the bridging wire 31 not only overlap the main wires 14 to constitute an electrical connection, respectively, but also overlap the lead wires 24 to constitute an electrical connection, respectively. The plurality of bridging wires 31 are implemented by existing, known techniques, such as impulse printing, side printing or edge sputter, and laser patterning.

In the first embodiment, the splicing surface 123 of the splicing board 11 is rendered flush with the splicing surface 123 of the lead board 21 either by calibration or through alignment followed by edging. After that, the plurality of bridging wires 31 are mounted in place.

With the lead board 21 being disposed on the rear side of the splicing board 11 relative to the plurality of bridging wires 31, the plurality of main wires 14 on the splicing board 11 can be connected to the plurality of lead wires 24 on the lead board 21. With the lead board 21 being disposed on the rear side of the splicing board 11, it can be provided with a control chip (not shown) or connected to any other circuit boards (not shown) without occupying the space above the upper surface 121 of the splicing board 11. Although the prior art taught reserving a lead zone on a splicing board in order for it to accommodate a control chip, the first embodiment of the disclosure discloses dispensing with the conventional lead zone and splicing the splicing board 11 with another splicing board 11 without causing an increase in the distance between the two adjacent splicing boards 11. Therefore, the disclosure is applicable to display panel splicing and effective in preventing image distortions or anomalies from occurring to the display panels. The disclosure is applicable to all display panels to splice, including existing, known Micro LED display panels and OLED display panels, but the disclosure is not limited thereto.

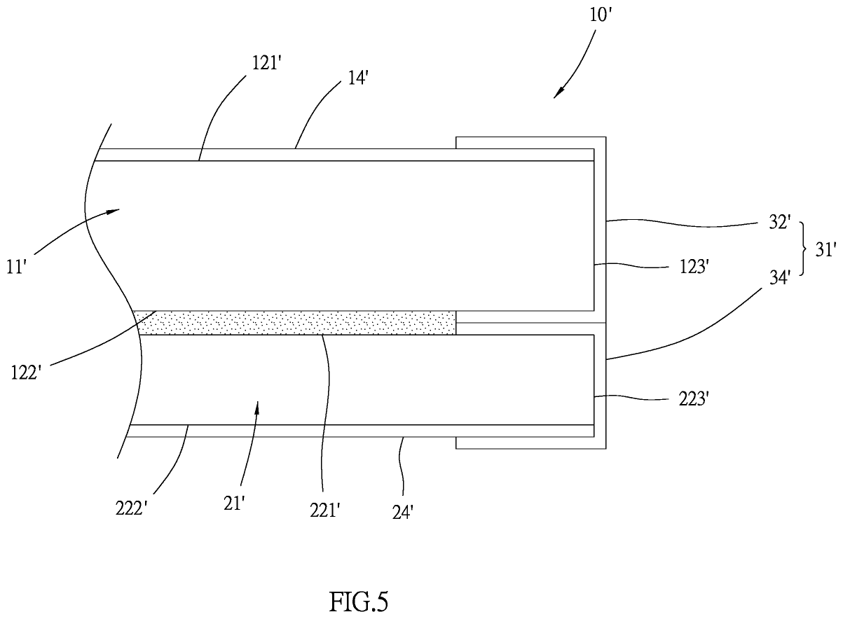

Referring to FIG. 5, a splicing unit 10′ for display panels is provided in a second preferred embodiment of the disclosure and distinguished from its counterpart in the first preferred embodiment of the disclosure by technical features described below.

Each bridging wire 31′ in the second preferred embodiment comprises an upper bridging wire 32′ and a lower bridging wire 34′ that are united, as opposed to one singe wire as disclosed in the first embodiment. One end of the upper bridging wire 32′ is connected to one of the main wires 14′ and positioned proximate to the upper surface 121′ of the splicing board 11′. The body of the upper bridging wire 32′ extends and crosses the splicing surface 123′ of the splicing board 11′. Then, the other end of the upper bridging wire 32′ is attached to the lower surface 122′ of the splicing board 11′. One end of the lower bridging wire 34′ is connected to one of the lead wires 24′ and positioned proximate to the lower surface 222′ of the lead board 21′. The body of the lower bridging wire 34′ extends and crosses the lead splicing surface 223′ of the lead board 21′. Then, the other end of the lower bridging wire 34′ is attached to the upper surface 221′ of the lead board 21′ and is in contact with a portion of the upper bridging wire 32′ on the lower surface 122′ of the splicing board 11′, so as to constitute an electrical connection.

As the aforesaid structure suggests, the second embodiment involves electrically connecting the plurality of main wires 14′ on the splicing board 11′ to the plurality of lead wires 24′ of the lead board 21′ by the plurality of upper bridging wires 32′ and the plurality of lower bridging wires 34′. This allows the plurality of upper bridging wires 32′ to be disposed on the splicing board 11′, then allows the plurality of lower bridging wires 34′ to be disposed on the lead board 21′, and finally allows the splicing board 11′ and the lead board 21′ to be overlapped and attached to each other.

The other structural features and achievable advantages of the second embodiment are substantially identical to those of the first embodiment and thus are not reiterated herein.

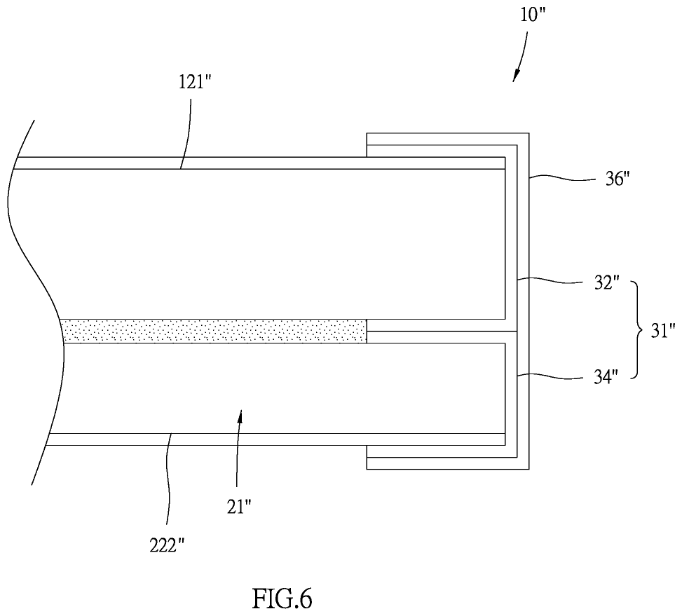

Referring to FIG. 6, a splicing unit 10″ for display panels is provided in a third preferred embodiment of the disclosure and distinguished from its counterpart in the second preferred embodiment of the disclosure by technical features described below.

In addition to the plurality of upper bridging wires 32″ and the plurality of lower bridging wires 34″, the third embodiment provides a plurality of united bridging wires 36″ such that the upper bridging wire 32″ and the lower bridging wire 34″ of each bridging wire 31″ are connected by one of the united bridging wires 36″.

One end of each united bridging wire 36″ is connected to one of the upper bridging wires 32″ and positioned proximate to the upper surface 121″ of the splicing board 11″. The body of the united bridging wire 36″ extends and crosses the upper bridging wire 32″ and the lower bridging wire 34″. Then, the other end of the united bridging wire 36″ is connected to one of the lower bridging wires 34″ and positioned proximate to the lower surface 222″ of the lead board 21″.

Therefore, the third embodiment is advantageously characterized by enhanced electrical connection of each united bridging wire 36″ to the upper bridging wire 32″ and the lower bridging wire 34″, enhancing the quality of electrical connection.

The other structural features and achievable advantages of the third embodiment are substantially identical to those of the second embodiment and thus are not reiterated herein.

What is claimed is:

1. A splicing unit for display panels, comprising:
a splicing board having an upper surface and a lower surface, with a plurality of main wires disposed on the upper surface of the splicing board, the splicing board having at least one lateral surface defined as a splicing surface;
a lead board having an upper surface and a lower surface, with a plurality of lead wires disposed on the lower surface of the lead board, the lead board having at least one lateral surface defined as a lead splicing surface, wherein the upper surface of the lead board is attached to the lower surface of the splicing board, and the splicing surface of the splicing board is substantially flush with the lead splicing surface of the lead board; and
a plurality of bridging wires connected to the plurality of main wires and the plurality of lead wires,
wherein each of the bridging wires has an end connected to one of the main wires and positioned proximate to the upper surface of the splicing board, and a body of the bridging wire extends and crosses the splicing surface of the splicing board and the lead splicing surface of the lead board, allowing another end of the bridging wire to be connected to one of the lead wires and positioned proximate to the lower surface of the lead board.

2. The splicing unit for display panels according to claim 1, wherein the bridging wires not only overlap and connect to the main wires, respectively, but also overlap and connect to the lead wires, respectively.

3. The splicing unit for display panels according to claim 1, wherein the splicing board and the lead board are adhered together with an adhesive.

4. The splicing unit for display panels according to claim 1, wherein each of the bridging wires comprises an upper bridging wire and a lower bridging wire that are united, the upper bridging wire having an end connected to one of the main wires and positioned proximate to the upper surface of the splicing board, the upper bridging wire having a body extending and crossing the splicing surface of the splicing board, the upper bridging wire having another end being attached to the lower surface of the splicing board, the lower bridging wire having an end connected to one of the lead wires and positioned proximate to the lower surface of the lead board, the lower bridging wire having a body extending and crossing the splicing surface of the lead board, the lower bridging wire having another end being attached to the upper surface of the lead board and being in contact with a portion of the upper bridging wire on the lower surface of the splicing board.

5. The splicing unit for display panels according to claim 4, further comprising a plurality of united bridging wires each connecting the upper bridging wire and the lower bridging wire of a corresponding one of the bridging wires.

6. The splicing unit for display panels according to claim 5, wherein the united bridging wires each have an end connected to one of the upper bridging wires and positioned proximate to the upper surface of the splicing board, a body extending and crossing the body of the upper bridging wire and the body of the lower bridging wire, and another end connected to one of the lower bridging wires and positioned proximate to the lower surface of the lead board.
